(19) United States
(12) Patent Application Publication
(10) Pub. No.: US 2024/0420931 A1
(43) Pub. Date: Dec. 19, 2024

(54) ROTATING SUBSTRATE SUPPORT

(71) Applicant: ASM IP Holding B.V., Almere (NL)

(72) Inventor: Yukihiro Mori, Tokyo (JP)

(21) Appl. No.: 18/817,577

(22) Filed: Aug. 28, 2024

Related U.S. Application Data
(63) Continuation of application No. 17/334,007, filed on May 28, 2021, now Pat. No. 12,106,944.
(60) Provisional application No. 63/033,743, filed on Jun. 2, 2020.

(51) Int. Cl. H01J 37/32; C23C 16/455; C23C 16/458; C23C 16/46; C23C 16/505; C23C 16/52; H01L 21/67; H01L 21/687

(52) U.S. Cl. CPC H01J 37/32715; C23C 16/45536; C23C 16/4584; C23C 16/46; C23C 16/505; C23C 16/52; H01L 21/67103; H01L 21/67248; H01L 21/68764; H01J 2237/20214; H01J 2237/3321

(57) ABSTRACT

An apparatus for processing a substrate may comprise a reaction chamber, a substrate support disposed within the reaction chamber and provided with a support surface to support the substrate, and a motor to provide a rotary movement, wherein the motor is controlled and configured to create a bidirectional rotary movement between the reaction chamber and the substrate support around an axis perpendicular to the support surface.

### CROSS-REFERENCE TO RELATED APPLICATIONS

This application is a continuation of, and claims priority to, U.S. patent application Ser. No. 17/334,007 filed May 28, 2021 titled ROTATING SUBSTRATE SUPPORT, which claims priority to U.S. Provisional Application No. 63/033,743, filed on Jun. 2, 2020 in the United States Patent and Trademark Office, the disclosures of which are incorporated herein in their entirety by reference.

### FIELD OF INVENTION

The present disclosure relates generally to a substrate processing apparatus and particularly a substrate support, which facilitates more uniform process across a surface within a reaction chamber, on a substrate.

### BACKGROUND OF THE DISCLOSURE

Integrated circuits comprise multiple layers of materials deposited by various techniques, including Chemical Vapor Deposition (CVD), Atomic Layer Deposition (ALD), Plasma Enhanced CVD (PECVD), and Plasma Enhanced ALD (PEALD). As such, the deposition of materials on a semiconductor substrate is a critical step in the process of producing integrated circuits. It is important to perform uniform processing on the surface of the substrate, but the processing result often varies for various reasons.

FIG. 1 shows a result of a film deposition with the PECVD apparatus and a film thickness distribution over the substrate. The variation of the film thickness may occur in a range of about 17 nm on a layer of about 170 nm due to various reasons such as, for example, temperature distribution, gas exhaust direction, and/or non-uniformity of electric field strength due to deviation of parallelism of electrodes.

In order to alleviate this problem, a rotating substrate support may be applied. However, it may be difficult to design such a rotating substrate support.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, an apparatus for processing a substrate is provided. The apparatus disclosed herein may allow adjustable material deposition on, and/or processing of, a substrate, for example, to achieve more uniform material deposition on, and/or processing of, the substrate.

In various embodiments, an apparatus for processing a substrate may comprise a reaction chamber, a substrate support disposed within the reaction chamber and provided with a support surface to support the substrate, and a motor to provide a rotary movement, wherein the motor is controlled and configured to create a bidirectional rotary movement between the reaction chamber and the substrate support around an axis perpendicular to the support surface. In various embodiments, the motor may be controlled and configured to create the rotary movement n times around (where n=1, 2, 3, . . . ). In various embodiments, n may be 1. In various embodiments, the motor may be controlled and configured to change the rotary direction when the rotary movement reaches n times around (where n=1, 2, 3, . . . ). In various embodiments, the motor may be controlled and configured to change the rotary direction from a first rotary direction to a second opposite rotary direction or vice versa when the rotary movement reaches n times around (where n=1, 2, 3, . . . ).

In various embodiments, the apparatus may further comprise a controller operably connected to the motor to control the bidirectional rotary movement created by the motor. In various embodiments, the apparatus may further comprise a rotary angle measurement device operably connected to the controller to measure an angle of rotation between the reaction chamber and the substrate support.

In various embodiments, the substrate support may be provided with an electrical device, and the electrical device may be connected with a wire to a station in the apparatus, and the wire may be constructed and arranged to allow for rotary movement over n times around (where n=1, 2, 3, . . . ) between the reaction chamber and the substrate support. In various embodiments, the electrical device may be an electrode of a plasma generator and the wire may be a RF wire. In various embodiments, the electrical device may be a temperature sensor (e.g. thermocouple) to measure a temperature, and the wire may be a temperature signal wire. In various embodiments, the electrical device may be a heater to heat the substrate and the wire may be a power wire for the heater. In various embodiments, the wire may comprise curled cord to allow for a rotary movement over n times around (where n=1, 2, 3, . . . ) between the reaction chamber and the substrate support.

In various embodiments, the substrate support may be connected to a rotatable shaft and the motor may be rotating the shaft. In various embodiments, the rotatable shaft may be protruding through a hole in the wall of the reaction chamber and the motor may be positioned outside the reaction chamber and seals arm may be provided around the rotary shaft to seal the reaction chamber off. In various embodiments, the substrate support may be supported on the shaft.

In various embodiments, a method of forming a film on a substrate supported by a substrate support may comprise providing a substrate within a reaction chamber, feeding a gas to the substrate, rotating the substrate support in a first rotary direction n times around (where n=1, 2, 3, . . . ), rotating the substrate support in a second opposite rotary direction n times around (where n=1, 2, 3, . . . ), and stopping to feed the gas to the substrate. In various embodiments, forming the film may be conducted by plasma enhanced atomic layer deposition (PEALD) or plasma enhanced chemical vapor deposition (PECVD).

In various embodiments, in a method of controlling an apparatus for processing a substrate, the apparatus may comprise: a reaction chamber, a substrate support disposed within the reaction chamber to support the substrate, and, a motor to provide a rotation between the substrate support and the reaction chamber, wherein controlling the apparatus comprises controlling that the number of rotations in a first rotary direction is substantially equal to the number of rotations in a second opposite rotary direction.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a result of film deposition with PECVD apparatus and the film thickness distribution;

FIG. 2 is a schematic diagram of an exemplary reactor apparatus;

FIG. 3 is a schematic diagram of an exemplary curled cord;

FIG. 4A is a schematic diagram of a conventional reaction chamber with a rotating substrate support;

FIG. 4B is a schematic diagram of an exemplary reaction chamber with a rotating substrate support; and

FIG. 5 is a timing sequence diagram in accordance with exemplary embodiments of the disclosure.

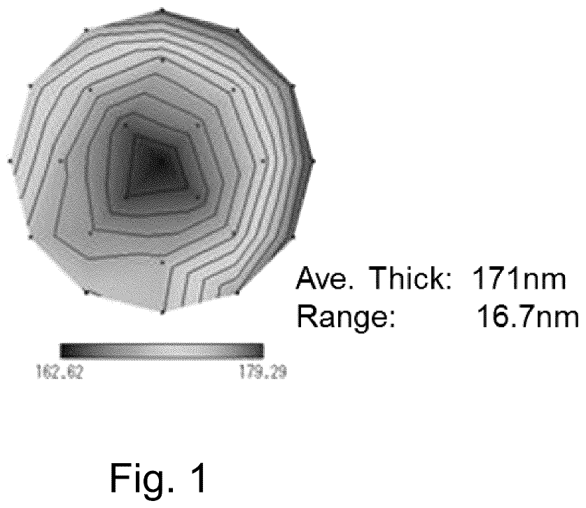

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As used herein, the term “substrate” may refer to any underlying material or materials that may be used, or upon which, a device, a circuit, or a film may be formed.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which react and/or decompose on a substrate surface to produce a desired deposition.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

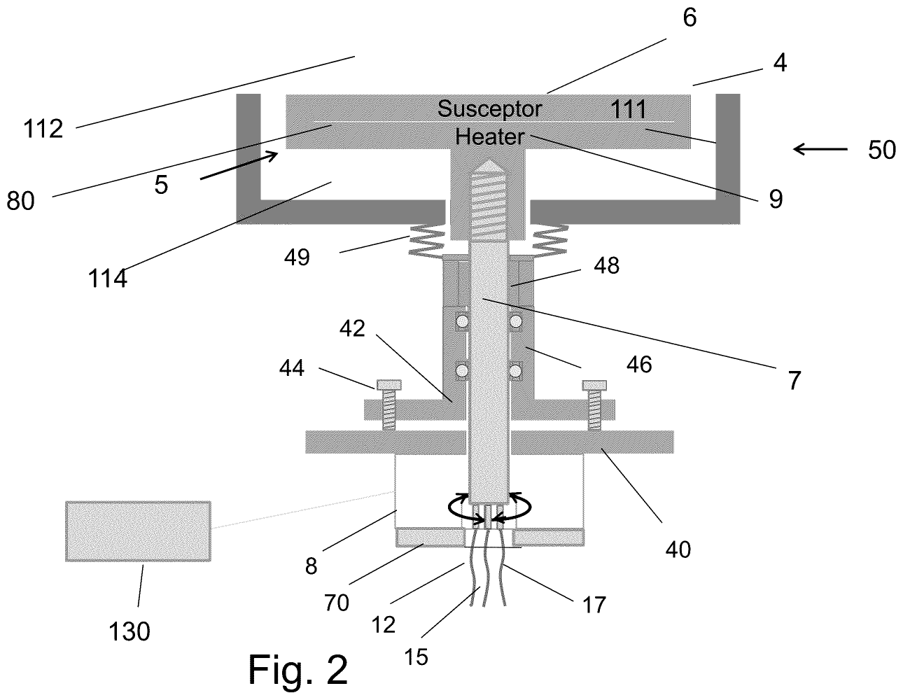

Reactor apparatus used for ALD, CVD, and/or the like, may be used for a variety of applications, including depositing and etching materials on a substrate surface. With reference to FIG. 2, a reactor apparatus 50 may comprise a reaction chamber 4, and a substrate support 5 (Susceptor) disposed within reaction chamber 4. The substrate support 5 may be provided with a support surface 6 to support a substrate. A motor 8 may provide a rotary movement, wherein the motor 8 is controlled and configured to create a bidirectional rotary movement between the reaction chamber 4 and the substrate support 5 around an axis perpendicular to the support surface 6.

The motor 8 may be controlled and configured to create the rotary movement n times around (where n=1, 2, 3, . . . ). The motor 8 may be controlled and configured to change the rotary direction when the rotary movement reaches n times around (where n=1, 2, 3, . . . ). The motor 5 may be controlled and configured to change the rotary direction from a first rotary direction to a second opposite rotary direction or vice versa when the rotary movement reaches n times around (where n=1, 2, 3, . . . ).

The apparatus 50 may further comprise a controller 130 operably connected to the motor 8 for controlling the bidirectional rotary movement created by the motor 8. The apparatus 50 may comprise a rotary angle measurement device 70 such as encoder operably connected to the controller 130 to measure an angle of rotation between the reaction chamber 4 and the substrate support 5.

The substrate support 5 may be provided with an electrical device, and the electrical device may be connected with a wire to a station in the apparatus 50, and the wire is constructed and arranged to allow for rotary movement over n times around (where n=1, 2, 3, . . . ) between the reaction chamber 4 and the substrate support 5. The electrical device may be an electrode 80 of a plasma generator and the wire is a RF wire 12. The electrical device may be a temperature sensor (e.g. thermocouple) to measure a temperature, and the wire may be a temperature signal wire 15. The electrical device may be a heater 9 to heat the substrate and the wire may be a power wire 17 for the heater 9.

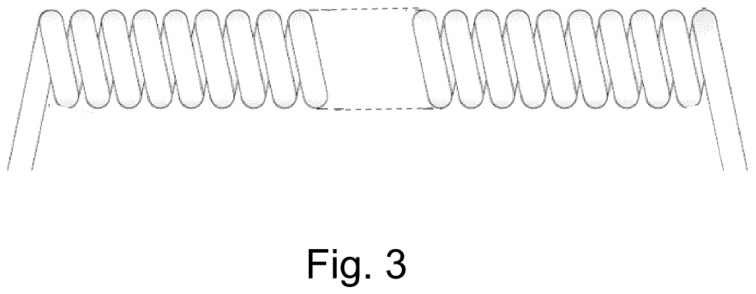

With reference to FIG. 3, the wire may comprise a curled cord to allow for a rotary movement over n times around (where n=1, 2, 3, . . . ) between the reaction chamber 4 and the substrate support 5.

The substrate support 5 may be connected to a rotatable shaft 7 and the motor 8 is rotating the shaft 7. The rotatable shaft 7 may be protruding through a hole in the wall of the reaction chamber 4 and the motor 8 may be positioned outside the reaction chamber 4 and the magnetic seals 48 may be provided around the rotatable shaft 7 to seal the reaction chamber 4.

The substrate support 5 may also include a tool frame 40, which is connected to the motor 8. A flange 42 may be connected to the flame 40 by bolts 44. The flange 42 may be movably coupled to the rotatable shaft 7 by suitable means, such as bearings 46. Bellows 49 is coupled between the bottom of the reaction chamber 4 and the magnetic seals 48.

The reaction chamber 4 may comprise a reaction space (i.e., an upper chamber), which may be configured for processing one or more substrates, and/or a lower chamber space 114 (i.e., a lower chamber). Lower chamber space 114 may be configured for the loading and unloading of substrates from the reaction chamber.

The reaction space 112 and the lower chamber space 114 may be separated by the substrate support 5. The reaction space 112 and the lower chamber space 114 may be substantially fluidly separate or isolated from one another. For example, a substrate support 5 may fluidly separate the reaction space 112 and the lower chamber space 114 by creating at least a partial seal (i.e., at least restricting fluid flow) between the substrate support 6 and a chamber sidewall 111 of the reaction chamber 4 disposed proximate a substrate support outer edge of the substrate support 5.

Substrate and the substrate support 5 may be movable relative to one another. For example, one or more lift pins (not shown) may be configured to allow substrate to separate from the substrate support 5, and to allow substrate to be placed in contact with (i.e., to be supported by) the substrate support 5. The substrate support 5 may move, for example via a substrate support elevator, up or down such that the substrate support 5 moves relative to substrate. In various embodiments, lift pins may move up or down, for example via lift pin elevators/platforms such that substrate moves relative to the substrate support 5. The substrate support 5 and/or lift pins may be stationary while the other is moving. The substrate support 5 and/or lift pins may be configured to move relative to the other.

During substrate processing (e.g., during PEALD, PECVD, and/or the like), an electric field may form around the substrate support 5 and the support surface 6 as electrons travel from the distribution system (e.g., showerhead) to the substrate support 5. The electric field around different portions of the substrate support 5 or the support surface 6 may differ, causing differing processing results on different portions of the substrate corresponding to the different proximate electric fields. Further, temperature distribution and gas exhaust direction may differ, causing differing processing results.

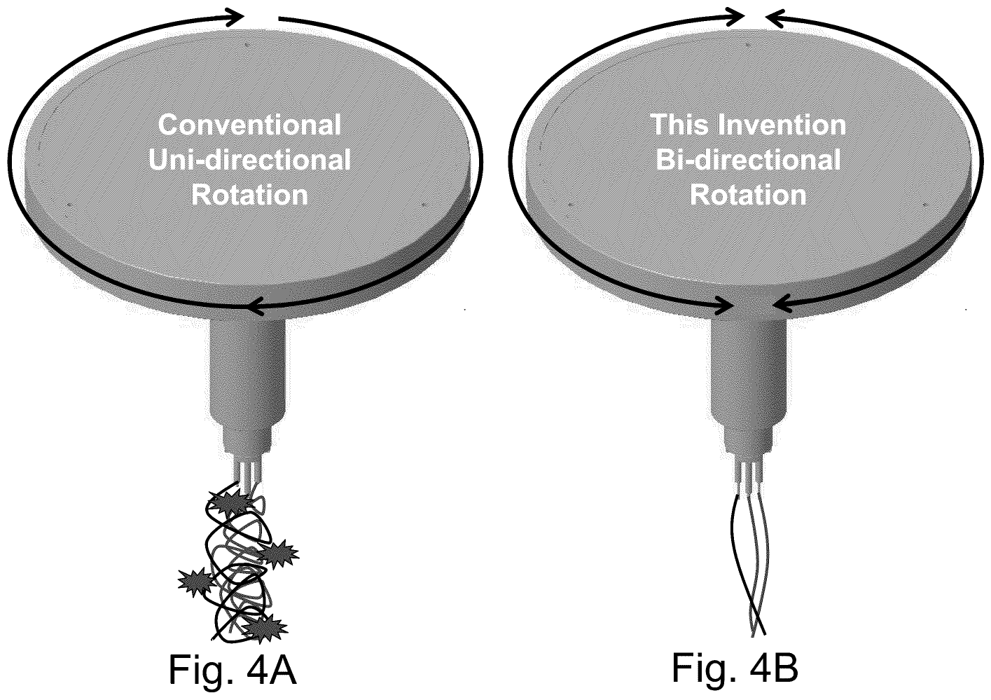

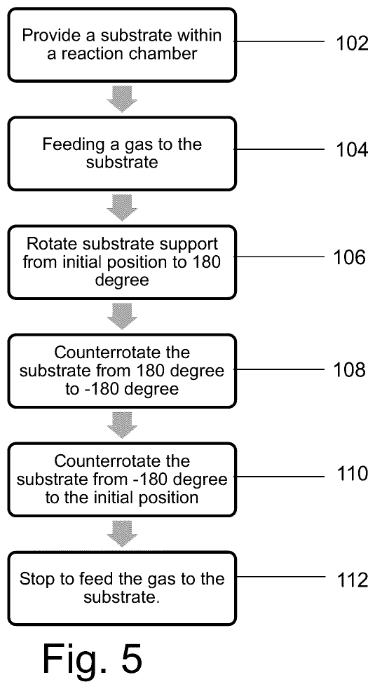

With additional reference to FIG. 4 and FIG. 5, a method for processing a substrate in a reaction chamber is illustrated. It should also be appreciated that the embodiments of the disclosure may be utilized in a reaction chamber configured for a multitude of deposition processes, including but not limited to, PEALD, PECVD, metalorganic chemical vapor deposition (MOCVD), molecular beam epitaxy (MBE), and physical vapor deposition (PVD). The embodiments of the disclosure may also be utilized in reaction chambers configured for processing a substrate with a reactive precursor, which may also include etch processes, such as, for example, reactive ion etching (RIE), inductively coupled plasma etching (ICP), and electron cyclotron resonance etching (ECR).

To avoid a difference of processing results and tangle of wires, the motor 8 may be controlled and configured to create a bidirectional rotary movement within a prescribed angle, preferably about 180 degrees. FIG. 5 illustrates an exemplary method. Method includes the steps of providing a substrate within the reaction chamber 4, feeding a gas to the substrate, the rotating substrate support 5 in a first rotary direction n times around (where n=1, 2, 3, . . . ); rotating the substrate support 5 in a second opposite rotary direction n times around (where n=1, 2, 3, . . . ); and stopping to feed the gas to the substrate.

During step 102 of providing a substrate within the reaction chamber 4, the substrate is provided into the reaction chamber 4. The reaction chamber 4 may form part of a cyclical deposition reactor, such as PEALD reactor or PECVD reactor. Various steps of methods described herein can be performed within a single reaction chamber or can be performed in multiple reaction chambers, such as reaction chambers of a cluster tool.

During step 104, a gas is fed into the reaction chamber 4. Gas may refer to material that is a gas at normal temperature and pressure, a vaporized solid and/or a vaporized liquid, and may be constituted by a single gas or a mixture of gases, depending on the context. A gas may be a process gas, i.e., a gas introduced passing through a gas distribution assembly, such as a showerhead, other gas distribution device, or the like, may be used.

During step 106, the substrate support 5 rotates from an initial position to 180 degrees. Rotation may be gradually or periodically, preferably gradually to improve uniformity of film thickness. During step 108, the substrate support 5 counter-rotates from 180 degrees to −180 degrees. During step 110, the substrate support 5 counter-rotates from −180 degrees to the initial position. During step 112, gas is stopped and process is completed.

Therefore, bidirectional rotary movement may improve, i.e., lowers the film thickness non-uniformity. Further, as shown in FIG. 4, the electric wires may not be damaged due to rotation.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. An apparatus for processing a substrate, comprising:
a reaction chamber;
a substrate support disposed within the reaction chamber and provided with a support surface to support the substrate;
a motor to provide a rotary movement of the substrate support, wherein the motor is controlled and configured to create a bidirectional rotary movement of the substrate support around a vertical axis; and
a controller operably connected to the motor to control the bidirectional rotary movement created by the motor, wherein the controller is configured to control the motor to rotate the substrate support from an initial position in a first direction, rotate the substrate support in a second direction, and then rotate the substrate support back to the initial position.

2. The apparatus of claim 1, wherein the vertical axis is perpendicular to the support surface and runs through a center of the support surface, and wherein the motor provides the rotary movement of the substrate support around the vertical axis.

3. The apparatus of claim 1, wherein the controller is configured to control the motor to rotate the substrate support in the first direction n times around (where n=1, 2, 3, . . . ).

4. The apparatus of claim 3, wherein n is 1.

5. The apparatus of claim 3, wherein the controller is configured to control the motor to change the rotary direction to the second direction when the rotary movement reaches n times around (where n=1, 2, 3, . . . ).

6. The apparatus of claim 1, wherein the controller is configured to control the motor to rotate the substrate support in the first direction 180 degrees.

7. The apparatus of claim 6, wherein the controller is configured to control the motor to change the rotary direction from the first direction to the second direction when the rotary movement reaches 180 degrees.

8. The apparatus of claim 1, further comprising a rotary angle measurement device operably connected to the controller to measure an angle of rotation between the reaction chamber and the substrate support.

9. An apparatus for processing a substrate, comprising:
a reaction chamber;
a substrate support disposed within the reaction chamber and provided with a support surface to support the substrate;
a rotatable shaft connected to the substrate support, wherein a vertical axis perpendicular to the support surface runs through the rotatable shaft and the center of the substrate support; and
a motor to provide a rotary movement of the substrate support by rotating the rotatable shaft around the vertical axis, wherein the motor is controlled and configured to create a bidirectional rotary movement of the substrate support around the vertical axis.

10. The apparatus of claim 9, wherein the rotatable shaft is protruding through a hole in the wall of the reaction chamber and the motor is positioned outside the reaction chamber and seals are provided around the rotatable shaft to seal the reaction chamber off.

11. The apparatus according to claim 10, wherein the substrate support is supported on the rotatable shaft.

12. The apparatus of claim 9, wherein the substrate support is provided with an electrical device, and the electrical device is connected with a wire to a station in the apparatus, and the wire is constructed and arranged to allow for bidirectional rotary movement between the reaction chamber and the substrate support.

13. The apparatus of claim 12, wherein the electrical device is an electrode of a plasma generator and the wire is a RF wire.

14. The apparatus of claim 12, wherein the electrical device is a temperature sensor to measure a temperature, and the wire is a temperature signal wire.

15. The apparatus of claim 12, wherein the electrical device is a heater to heat the substrate and the wire is a power wire for the heater.

16. The apparatus of claim 12, wherein the wire comprises a curled cord to allow for a rotary movement between the reaction chamber and the substrate support.

17. A method of processing a substrate supported by a substrate support, comprising:
providing a substrate on the substrate support within a reaction chamber;
feeding a gas to the substrate;
rotating the substrate support around a center of the substrate support in a first rotary direction;
rotating the substrate support around the center of the substrate support in a second opposite rotary direction; and
stopping to feed the gas to the substrate,
wherein processing the substrate comprises forming a film by a cyclical deposition process, or etching a film by reactive ion etching (RIE), inductively coupled plasma etching (ICP), or electron cyclotron resonance etching (ECR).

18. The method of claim 17, wherein rotating the substrate support in a first rotary direction comprises rotating the substrate support 180 degrees.

19. The method of claim 17, wherein rotating the substrate support in a first rotary direction comprises rotating the substrate support n times around (where n=1, 2, 3, . . . ).

20. The method of claim 17. wherein the substrate support is at an initial position before rotating the substrate support in the first rotary direction, and wherein the substrate support is at the initial position after rotating the substrate support in the second rotary direction.
